(19) United States
(12) Patent Application Publication
(10) Pub. No.: US 2006/0086321 A1
(43) Pub. Date: Apr. 27, 2006

(54) Substrate-to-mask alignment and securing system with temperature control for use in an automated shadow mask vacuum deposition process

(75) Inventors: Thomas Peter Brody, Pittsburgh, PA (US); Paul R. Malmberg, Pittsburgh, PA (US); Jeffrey W. Conrad, Verona, PA (US)

Correspondence Address: THE WEBB LAW FIRM, P.C., 700 KOPPERS BUILDING, 436 SEVENTH AVENUE, PITTSBURGH, PA, 15219, US

(73) Assignee: Advantech Global, LTD, Tortola (VG)

(21) Appl. No.: 10/971,218

(22) Filed: Oct. 22, 2004

(51) Int. Cl. C23C 16/00

(52) U.S. Cl. 118/720; 118/728; 427/248.1

(57) ABSTRACT

The present invention is a substrate holder system for and method of providing a substrate-to-mask alignment mechanism, securing mechanism and temperature control mechanism. The substrate holder system is suitable for use in an automated shadow mask vacuum deposition process. The substrate holder system includes a system controller, and a substrate arranged between a magnetic chuck assembly and a mask holder assembly. The magnetic chuck assembly includes a magnetic chuck, a thermoelectric device, a plurality of thermal sensors and a plurality of light sources. The mask holder assembly includes a shadow mask, a mask holder, a motion control system and a plurality of cameras. The substrate holder system of the present invention provides close contact between the substrate and the shadow mask thereby avoiding the possibility of evaporant material entering into a gap therebetween.

### BACKGROUND OF THE INVENTION

1. Field of the Invention

The present invention relates to shadow mask vacuum deposition and, more particularly, to a substrate holder system for use with a shadow mask vacuum deposition system.

2. Description of Related Art

Thin-film display panels, such as liquid crystal displays or electroluminescent displays, are used for displaying information. Such displays include thin-film devices, such as electrodes and contact pads, deposited on a substrate in a manner to form a matrix display panel having individually energizable pixels. One of the challenges encountered in the manufacture of such display panels is the development of improved processes that pattern the thin-film electrode structures while they are in an in-line deposition system.

Thin-film devices of such displays are typically formed by photolithography or by shadow masking. Photolithography includes depositing a photosensitive material on a substrate, coating the photosensitive material with light-sensitive material, which is then exposed to a negative or positive pattern and developed and later stripped in various corrosive developing solutions. A disadvantage of this process includes its numerous labor intensive steps, each of which is subject to failure or possible contamination of the thin-film device.

Shadow masking is usually performed over small substrates with stiff masks that are manually clamped to ensure even contact with a particular substrate. Shadow masking is a relatively slow process and usually requires breaking vacuum in the deposition chamber which may result in some thin-film contamination. When using a large-area shadow mask in a deposition process, it is common that the substrate is not perfectly flat or not level with respect to its surrounding substrate holder. Additionally, most shadow masking processes required manually dropping each shadow mask over pins located on a substrate carrier.

In a shadow mask vacuum deposition process, each shadow mask is desirably in close contact with the corresponding substrate so that there is little or no gap between the shadow mask and the substrate whereupon the inadvertent deposition of material on undesirable area(s) of the substrate is avoided. Furthermore, in a shadow mask vacuum deposition process, it is desirable to have a uniform temperature across the area of the shadow mask in order to avoid misregistration caused by non-uniform expansion. For example, non-uniform expansion may cause the mask to be non-planar. Any such non-uniformity caused by expansion increases the possibility for inaccuracies in the deposition process.

Therefore, what is needed, and not disclosed in the prior art is a method and apparatus for use in a shadow mask vacuum deposition process that avoids material from being deposited in area(s) not defined by aperture(s) in the shadow mask and which also avoids temperature variations across the full area of the shadow mask in order to avoid misregistration between the substrate and the aperture(s) in the shadow mask.

### SUMMARY OF THE INVENTION

The invention is a material deposition system that includes a magnetic chuck that can be switched between a first state wherein magnetic flux generated by the magnetic chuck propagates from a contacting surface thereof and a second state wherein no magnetic flux propagates from the contacting surface thereof. The system includes a magnetically conductive shadow mask having a contacting surface. Lastly, the system includes means for movably supporting the contacting surface of the shadow mask in spaced parallel relation with the contacting surface of the magnetic chuck. In response to switching the magnetic chuck from its second state to its first state when a substrate is positioned between the contacting surface of the magnetic chuck and the contacting surface of the shadow mask, the magnetic flux generated by the magnetic chuck causes the shadow mask to be pulled toward the magnetic chuck thereby clamping the substrate between the contacting surface of the magnetic chuck and the contacting surface of the shadow mask.

In response to switching the magnetic chuck from the first state to the second state, the supporting means moves the shadow mask away from the magnetic chuck thereby forming a space between the substrate and the contacting surface of the shadow mask.

A material deposition source can be positioned on a side of the shadow mask opposite the magnetic chuck. The material deposition source can be operated to deposit a material on the substrate via the shadow mask when the substrate is clamped between the contacting surface of the magnetic chuck and the contacting surface of the shadow mask.

At least one thermal sensor can be provided for sensing a temperature of the magnetic chuck. A device can also be provided for heating or cooling the magnetic chuck to a desired temperature as a function of the temperature sensed by the thermal sensor.

A light source operative for outputting a beam of light can be coupled to the magnetic chuck or the supporting means. A camera can be coupled to the other of the magnetic chuck and the supporting means. A system controller can be provided for receiving an image output by the camera and for controlling the supporting means or a position of the substrate as a function of the image whereupon the camera is positioned to view the light beam output by the light source via a hole in the substrate.

The supporting means can include a mask holder coupled to a side of the shadow mask opposite the magnetic chuck and a motion control system coupled to a side of the mask holder opposite the shadow mask. The light source can be coupled to one of the magnetic chuck and the mask holder and the camera can be coupled to the other of the magnetic chuck and the mask holder. The system controller can receive the image output by the camera and can control at least one of the motion control system and the position of the substrate as a function of the received image.

The magnetic chuck, the shadow mask and the supporting means can be positioned in a vacuum vessel. A means for translating can be provided for translating at least a portion of the substrate into and out of the vacuum vessel.

The invention is also a vapor deposition method that includes: (a) positioning at least a portion of a substrate between a contacting surface of a magnetic chuck and a contacting surface of a shadow mask; (b) switching the magnetic chuck from a first state wherein no magnetic flux propagates from the contacting surface thereof to a second state wherein magnetic flux propagates from the contacting surface thereof whereupon the shadow mask is pulled toward the magnetic chuck thereby clamping the substrate between the contacting surface of the magnetic chuck and the contacting surface of the shadow mask; and (c) depositing a material on the substrate via at least one opening in the substrate.

The magnetic chuck can be switched from its second first state to its first state whereupon the shadow mask moves away from the magnetic chuck thereby forming a gap between the substrate and the contacting surface of the shadow mask. The portion of the substrate can then be translated from between the contacting surface of the magnetic chuck and the contacting surface of the shadow mask.

The magnetic chuck can be heated or cooled to a desired temperature. The heating or cooling of the magnetic chuck to the desired temperature can be controlled as a function of an actual temperature of the magnetic chuck.

Between step (b) and step (c) the method can include, in response to determining that the substrate and the shadow mask are misaligned, switching the magnetic chuck from its second state to its first state whereupon the shadow mask moves away from the magnetic chuck thereby forming a gap between the substrate and the contacting surface of the shadow mask. At least one of the substrate and the shadow mask can then be repositioned whereupon the substrate and the shadow mask are properly aligned. The magnetic chuck can then be switched from its first state to its second state whereupon the substrate is re-clamped between the contacting surface of the magnetic chuck and the contacting surface of the shadow mask.

The invention is also a material deposition system that includes a magnetic chuck operative between a first state where magnetic flux propagates from a contacting surface thereof and a second state wherein no magnetic flux propagates from the contacting surface thereof, and a magnetically conductive shadow mask having a contacting surface positioned in spaced relation to the contacting surface of the magnetic chuck. The system also includes means for supporting a substrate between the contacting surface of the magnetic chuck and the contacting surface of the shadow mask. In response to the magnetic chuck entering its first state, the shadow mask and the magnetic chuck clamp the substrate between the contacting surfaces thereof. In response to the magnetic chuck entering its second state the shadow mask and the magnetic chuck release the substrate.

The system can include a material deposition source operative for depositing a material on the substrate via one or more apertures in the shadow mask. The magnetic chuck, the shadow mask, the substrate and the material deposition source can be positioned in a vacuum vessel. The material deposition source can deposit the material on the substrate in the presence of a vacuum in the vacuum vessel.

A temperature sensor can sense a temperature of the magnetic chuck and/or the shadow mask and can output a temperature signal corresponding to the sensed temperature. A temperature control device can control the temperature of the magnetic chuck and/or the shadow mask as a function of the temperature signal output by the temperature sensor.

A mask holder can support the shadow mask and a motion control system can support the mask holder and the shadow mask. The motion control system can be operated to rotate the mask holder and the shadow mask around an axis normal to the contacting surface of the shadow mask, translate the mask holder and the shadow mask in a direction parallel to the axis, and/or translate the mask holder and the shadow mask in at least one direction perpendicular to the axis.

A light source operative for outputting a beam of light can be coupled to one of the magnetic chuck and the mask holder. A camera operative for outputting an image of an object positioned in a field of view of the camera can be coupled to the other of the magnetic chuck and the mask holder. A system controller can be operated for receiving the image output by the camera and for controlling at least one of the motion control system and a position of the substrate as a function of the image whereupon the camera is positioned to view the light beam output by the light source via a hole in the substrate.

Lastly, the invention is a vacuum deposition method that includes: (a) magnetically clamping a substrate between a chuck and a shadow mask; (b) depositing a material on the substrate via at least one opening in the substrate; and (c) releasing the magnetic clamp on the substrate whereupon at least one of the chuck and the shadow mask moves into spaced relation with the substrate whereupon the substrate can be translated from a position between the chuck and the shadow mask.

### BRIEF DESCRIPTION OF THE DRAWINGS

FIG. 1 illustrates an exemplary production system for performing shadow mask vacuum deposition;

FIG. 2A illustrates a side view of a substrate holder system in accordance with the present invention in a non-activated state;

FIG. 2B illustrates a side view of the substrate holder system of FIG. 2A in an activated state; and

FIG. 3 is a flow diagram of a method of using the substrate holder system of the present invention in an automated continuous production process.

### DETAILED DESCRIPTION OF THE INVENTION

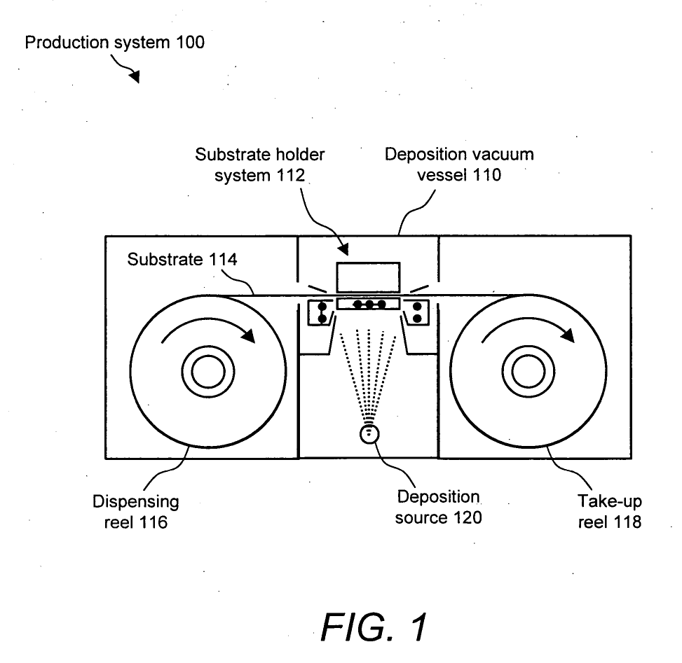

With reference to FIG. 1, a production system 100 for performing shadow mask vacuum deposition includes a deposition vacuum vessel 110 having therein a substrate holder system 112 for securing a substrate 114 during a deposition operation. Substrate 114 is formed of, for example, anodized aluminum, flexible steel foil, glass or plastic. Physical reference features are formed on substrate 114 in the form of, for example, punched holes or deposited patterns. These physical reference features are used to properly align substrate 114 to substrate holder system 112. Substrate 114 translates through deposition vacuum vessel 110 by way of a reel-to-reel mechanism that includes a dispensing reel 116 and a take-up reel 118.

Deposition vacuum vessel 110 further includes at least one deposition source 120 which can supply deposition source material, such as metal, semiconductor, insulator, or organic electroluminescent material, to be deposited via an evaporation process.

Production system 100 is not limited to one deposition vacuum vessel 110, as shown in FIG. 1. Rather, production system 100 may include two or more deposition vacuum vessels 110 arranged serially, depending on the number of deposition events required for any given product to be formed therewith. Those skilled in the art will appreciate that production system 100 may include additional stages (not shown), such as an anneal stage, a test stage, one or more cleaning stages, a cut and mount stage, and the like, as is well-known. Furthermore, production system 100 is not limited to a reel-to-reel system for manipulating substrate 114. Alternatively, production system 100 is a non-reel-to-reel system, i.e., a piece processing system. An example of a suitable production system 100 is disclosed in U.S. Patent Application Publication No. 2003/0228715, entitled “Active Matrix Backplane For Controlling Controlled Elements And Method Of Manufacture Thereof”, which is incorporated herein by reference.

Deposition vacuum vessel 110 is utilized for depositing materials from one or more deposition sources 120 onto substrate 114 to form one or more electronic elements on substrate 114. Each electronic element may be, for example, a thin film transistor (TFT), a diode, a memory element or a capacitor. A multi-layer circuit can be formed on substrate 114 solely by the successive deposition of materials via successive deposition events within a serial arrangement of multiple deposition vacuum vessels 110.

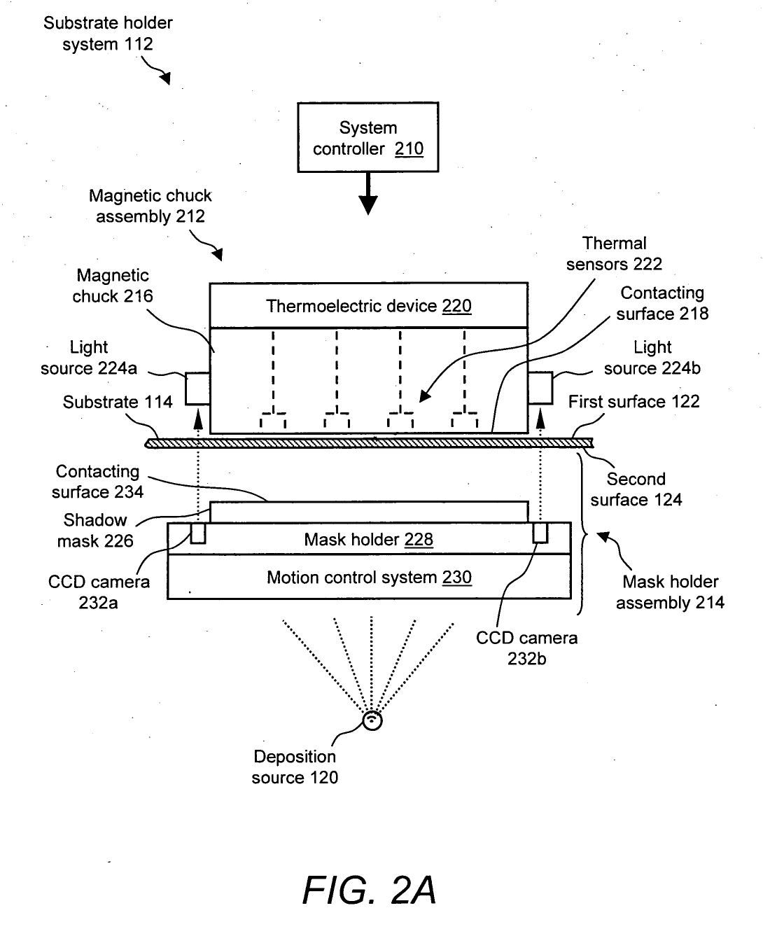

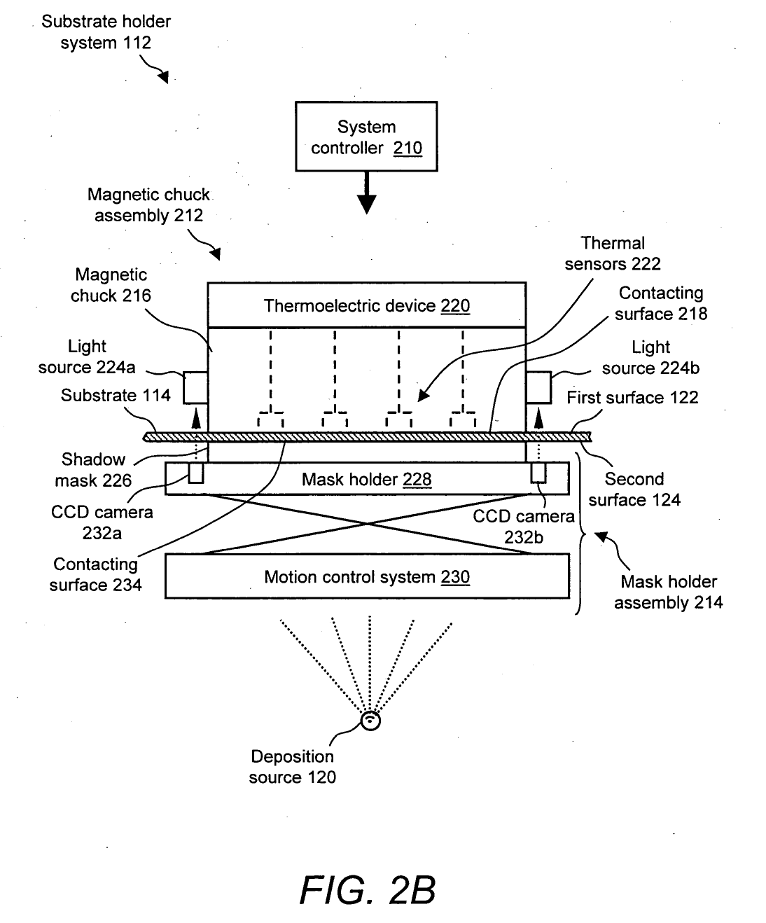

With reference to FIG. 2A and with continuing reference to FIG. 1, substrate holder system 112 includes a system controller 210, a magnetic chuck assembly 212 and a mask holder assembly 214.

Magnetic chuck assembly 212 includes a magnetic chuck 216 that has a contacting surface 218 facing toward a first surface 122 of substrate 114, a thermoelectric device 220 that is thermally coupled to magnetic chuck 216 and electrically coupled to a plurality of thermal sensors 222 installed at or adjacent contacting surface 218 of magnetic chuck 216, and light sources 224a and 224b arranged at the outer perimeter of magnetic chuck 216.

Mask holder assembly 214 includes a shadow mask 226 that is mounted upon a mask holder 228, a motion control system 230 for providing X-, Y-, Z-, and theta-position adjustment to mask holder 228 and, thereby, to shadow mask 226, and a plurality of charged coupled device (CCD) cameras 232a and 232b. Each CCD camera 232 of mask holder assembly 214 is associated with a respective light source 224 of magnetic chuck assembly 212. A contacting surface 234 of shadow mask 226 faces a second surface 124 of substrate 114. Operating under the control of a control program, system controller 210 manages the operation of magnetic chuck assembly 212. More particularly, system controller 210 receives inputs from thermal sensors 222, receives images from cameras 232 and outputs control signals that control the operation of magnetic chuck 216, thermoelectric device 220, light sources 224 and/or motion control system 230.

Magnetic chuck 216 is commercially available and is formed of a magnetic material that has a large mass, as compared with the mass of substrate 114 and shadow mask 226. Contacting surface 218 of magnetic chuck 216 is desirably smooth and planar. In one embodiment, magnetic chuck 216 generates a magnetic field in response to electrical stimulation. More specifically, in this one embodiment, magnetic chuck 216 is a pulsed electromagnet wherein a short pulse of current generates a first high intensity magnetic field. The magnetic material that forms magnetic chuck 216, however, has a high residual flux density whereupon when the current pulse is ended, a second high intensity magnetic field remains. Desirably, the second high intensity magnetic field has the same flux density as the first high intensity magnetic field. However, this is not to be construed as limiting the invention since the second high intensity magnetic field can have a flux density less than the first high intensity magnetic field provided the second high intensity magnetic field has a flux density suitable for the present application. A reverse current pulse of suitable magnitude causes the intensity of the second high intensity magnetic field of magnetic chuck 216 to return to zero. In this way, the magnetic field of magnetic chuck 216 can be switched between the second high intensity magnetic field and zero. Because of the shortness of the current pulse, very little heat is generated when magnetic chuck 216 is energized and, thus, magnetic chuck 216 contributes very little heat to the overall system. Magnetic chuck 216 also has an associated power supply (not shown).

Magnetic chuck 216 and, thus, contacting surface 218 of magnetic chuck 216, is sized according to the size of the product to be formed via the shadow mask vacuum deposition process. For example, to form a 16-inch diagonal display panel, contacting surface 218 of magnetic chuck 216 is approximately 10×13 inches. An exemplary manufacturer of magnetic chuck 216 in the form of a pulsed electromagnetic is Eclipse Magnetics of Sheffield, England.

In an alternate embodiment, magnetic chuck 216 is a mechanically switched magnet whose poles are engaged or disengaged pneumatically or manually via a lever. An exemplary manufacturer of a mechanically switched magnetic chuck is Eclipse Mechanics of Sheffield, England.

Thermoelectric device 220 is a commercially available Peltier junction-type device that can provide either heating or cooling to magnetic chuck 216, depending on the direction of electrical current flowing through thermoelectric device 220. Thermoelectric device 220 is electrically coupled to thermal sensors 222, which provide feedback regarding the temperature of contacting surface 218 of magnetic chuck 216. Thermal sensors 222 are, for example, standard temperature sensing devices installed within cavities at or adjacent contacting surface 218 of magnetic chuck 216.

Thermoelectric device 220 is capable of providing heating and cooling in the range of 0.1 to 5 watts/second. Because substrate 114 and shadow mask 226 are stabilized to approximately room temperature during the shadow mask vacuum deposition process, thermoelectric device 220 need only be capable of heating or cooling substrate 114 no greater than ±40 degrees C. Example manufacturers of thermoelectric device 220 include Tellurex Corporation of Traverse City, Mich. and Thermo Electron Corporation of Waltham, Mass.

Light sources 224 of magnetic chuck assembly 212 are standard light source devices. Each light source 224 provides a suitably intense beam of light that is directed at an associated CCD camera 232. Each CCD camera 232 is a light-sensitive device of the type that is used in most digital cameras to convert the light entering through a lens from a field of view of the camera into electronic signals that can be digitally processed and/or viewed on a video monitor unit. Each CCD camera 232 is mounted within the frame of mask holder 228 in a fixed and known position relative to shadow mask 226 which is also mounted upon mask holder 228.

The combination of system controller 210, light sources 224 and CCD cameras 232 form an exemplary machine vision system that can perform position measurements using well-known image processing and feature recognition techniques implemented in software. Therefore, the use of system controller 210, light sources 224 and CCD cameras 232 provides the capability to accurately align shadow mask 226 to substrate 114. However, those skilled in the art will appreciate that there are a number of well-known alignment techniques and instrumentation that may be used alternatively to the combination of system controller 210, light sources 224 and CCD cameras 232.

The combination of magnetic chuck 216 and thermoelectric device 220 is held stationary within, for example, deposition vacuum vessel 110 of production system 100.

Shadow mask 226 is formed of a magnetic material, such as nickel, steel, Kovar or Invar, and has a thickness of, for example, 50-200 microns. Kovar and Invar can be obtained from, for example, ESPICorp Inc. of Ashland, Oreg. In the United States, Kovar® is a registered Trademark, United States Trademark Registration No. 337,962, currently owned by CRS Holdings, Inc. of Wilmington, Del. In the United States, Invar® is a registered Trademark, United States Trademark Registration No. 63,970, currently owned by Imphy S.A. Corporation of France. Shadow mask 226 includes a pattern of apertures (not shown), e.g., slots and holes, as is well-known. The pattern of apertures in shadow mask 226 corresponds to a desired pattern of material to be deposited on substrate 114 from deposition source 120 within deposition vacuum vessel 110 as substrate 114 is advanced therethrough.

Mask holder 228 is a frame structure that is desirably formed of a suitably rigid non-magnetic material, such as copper or aluminum, in order to avoid shorting the magnetic flux generated by magnetic chuck 216. Alternatively, mask holder 228 is formed of a magnetic material, such as steel, Invar or Kovar. Mask holder 228 has, for example, a planar raised ridge (not shown) for bonding the perimeter of shadow mask 226 thereon. Bonding may be facilitated by an adhesive, resistance welding, or brazing. Additionally, shadow mask 226 is bonded to mask holder 228 with a desired tension using known techniques. A clearance area (not shown) is provided within the center region of mask holder 228 to allow evaporant from a deposition source, such as deposition source 120, to pass therethrough and, subsequently, to allow the evaporant to pass through the aperture(s) of shadow mask 226. Mask holder 228 is sized according to an expected size of shadow mask 226 or is alternatively designed to handle a range of shadow mask 226 sizes. Additionally, mask holder 228 is mechanically coupled to a standard motion control system 230 for providing X-, Y-, Z-, and theta-position adjustment to mask holder 228 and, thereby, to shadow mask 226. An exemplary manufacturer of a standard motion control system that is suitable for use with mask holder assembly 214 is Aerotech Inc. of Pittsburgh, Pa.

When substrate holder system 112 of the present invention is in a non-activated state, first surface 122 of substrate 114 is not in intimate contact with contacting surface 218 of magnetic chuck 216 and substrate 114 is free to translate longitudinally in a plane parallel to contacting surface 218 and contacting surface 234 of magnetic chuck 216 and shadow mask 226, respectively, via, for example, the rotation motion of dispensing reel 116 and take-up reel 118 of production system 100.

With reference to FIG. 2B and with continuing reference to FIGS. 1 and 2A, when substrate holder system 112 is in an activated state, first surface 122 of substrate 114 is in intimate contact with contacting surface 218 of magnetic chuck 216, and contacting surface 234 of shadow mask 226 is held in contact with second surface 124 of substrate 114. As a result, substrate 114 is tightly secured between magnetic chuck 216 and shadow mask 226 whereupon substrate 114 is not free to move.

In operation of substrate holder system 112, magnetic chuck 216 and thermoelectric device 220 are initially de-energized whereupon first surface 122 and second surface 124 of substrate 114 are spaced from contacting surface 218 and contacting surface 234 of magnetic chuck assembly 212 and mask holder assembly 214, respectively, as shown in FIG. 2A. Substrate 114 and shadow mask 226 are aligned by use of CCD cameras 232, light sources 224, and motion control system 230. More specifically, light from light sources 224 pass through alignment holes (not shown) in substrate 114 for receipt by CCD cameras 232. Under the control of motion control system 230, the position of mask holder 228 and, thereby, shadow mask 226 is adjusted to bring each CCD camera 232 into alignment with its corresponding light source 224 and the corresponding alignment aperture in substrate 114. If desired, motion control system 230 can be operative for controlling the translation of substrate 114 to facilitate alignment between each CCD camera 232, its corresponding light source 224 and the corresponding aperture in substrate 114.

Shadow mask 226 is then moved in close proximity to substrate 114 via the Z-position adjustment of motion control system 230. Magnetic chuck 216 is then activated to produce a magnetic field that propagates from contacting surface 218 thereof and pulls shadow mask 226 toward magnetic chuck 216 whereupon first surface 122 of substrate 114 is pulled into contact with contacting surface 218 of magnetic chuck 216 and contacting surface 234 of shadow mask 226 is pulled into contact with second surface 124 of substrate 114. Thus, the activation of magnetic chuck 216 causes substrate 114 to be clamped between contacting surface 234 of shadow mask 226 and contacting surface 218 of magnetic chuck 216.

Thermoelectric device 220 is then activated to heat or cool, as necessary, magnetic chuck 216, substrate 114 and shadow mask 226 to a predetermined temperature. When first and second surfaces 122 and 124 of substrate 114 are in contact with contacting surfaces 218 and 234 of magnetic chuck 216 and shadow mask 226, respectively, material evaporated from deposition source 120 passes through the aperture(s) of shadow mask 226 and condenses upon second surface 124 of substrate 114.

Upon completing deposition of the material from deposition source 120, magnetic chuck 216 and thermoelectric device 220 are deactivated. With magnetic chuck 216 deactivated, motion control system 230 adjusts the Z-position of mask holder 228 whereupon contacting surface 234 is caused to move away from second surface 124 of substrate 114, e.g., to the position shown in FIG. 2A, whereupon the section of substrate 114 between magnetic chuck 216 and shadow mask 226 can be translated in a plane parallel to contacting surface 218.

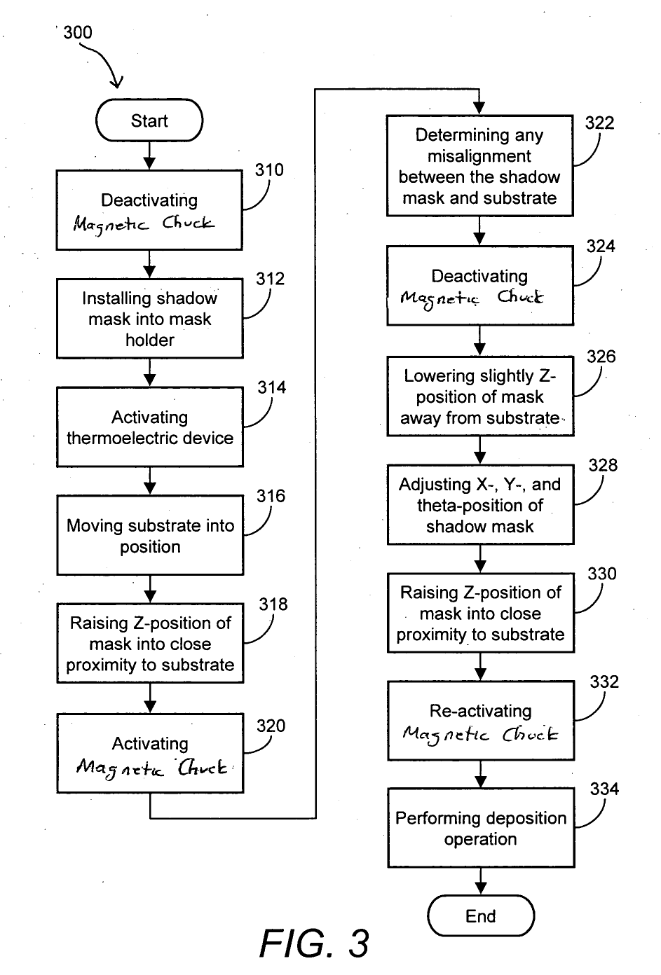

With reference to FIG. 3 and with continuing reference to FIGS. 1, 2A and 2B, a method 300 of using substrate holder system 112 includes step 310 wherein under the control of system controller 210, magnetic chuck 216 is held in a de-energized or deactivated state whereupon no magnetic field is generated for pulling shadow mask 226 toward magnetic chuck 216. As a result, substrate 114 is free to translate between magnetic chuck 216 and shadow mask 226 in a plane parallel to contacting surface 218 of magnetic chuck 216.

The method then advances to step 312, wherein shadow mask 226 is secured on mask holder 228 in a fixed and known position relative to CCD cameras 232 by, for example, an adhesive, resistance welding or brazing.

The method then advances to step 314, wherein, under the control of system controller 210, thermoelectric device 220 is activated thereby generating heat or cold for holding magnetic chuck 216, substrate 114, and shadow mask 226 at a predetermined temperature, such as room temperature, when substrate 114 is in contact with magnetic chuck 216 and shadow mask 226. Feedback from thermal sensors 222 located at or adjacent contacting surface 218 of magnetic chuck 216 are the mechanism for determining when the predetermined temperature is reached.

The method then advances to step 316, wherein, substrate 114 is translated into the proper position relative to substrate holder system 112 via, for example, the rotation of dispensing reel 116 and take-up reel 118 of production system 100.

The method then advances to step 318, wherein, under the control of system controller 210, the Z-position of mask holder 228 is adjusted by use of motion control system 230 to move contacting surface 234 of shadow mask 226 into close proximity with second surface 124 of substrate 114.

The method then advances to step 320, wherein, under the control of system controller 210, magnetic chuck 216 is energized whereupon a magnetic field propagates from contacting surface 218 and pulls shadow mask 226, which is formed of magnetic material, toward magnetic chuck 216. As a result, first surface 122 of substrate 114 is held in contact with contacting surface 218 of magnetic chuck 216, and contacting surface 234 of shadow mask 226 is held in contact with second surface 124 of substrate 114. Consequently, substrate 114 is clamped or compressed between magnetic chuck 216 and shadow mask 226.

The method then advances to step 322, wherein, under the control of system controller 210, it is determined whether there is misalignment between shadow mask 226 and substrate 114 using any well-known vision or optical measurement system. For example, the combination of system controller 210, light sources 224 and CCD cameras 232 form an exemplary machine vision system that can perform position measurements using well-known image processing and feature recognition techniques implemented in software running on system controller 210. In the case of substrate 114 having punched holes as the alignment reference features, light sources 224 are activated and CCD cameras 232 visually detect the position of the punched alignment features of substrate 114. Because the position of CCD cameras 232 relative to shadow mask 226 is known, the position of substrate 114 relative to shadow mask 226 can be determined and transmitted to system controller 210. System controller 210 then compares the actual position of substrate 114 relative to shadow mask 226 to an expected position, thereby defining the position error, if any. System controller 210 then transmits suitable position correction information to motion control system 230.

The method then advances to step 324, wherein, under the control of system controller 210, magnetic chuck 216 is de-energized whereupon no magnetic field is generated for pulling shadow mask 226 toward magnetic chuck 216. As a result, first surface 122 of substrate 114 is no longer pulled into contact with contacting surface 218 of magnetic chuck 216, and contacting surface 234 of shadow mask 226 is no longer pulled into contact with second surface 124 of substrate 114. Desirably, when magnetic chuck 216 is de-energized, a space or gap is formed between substrate 114 and at least one of magnetic chuck 216 and shadow mask 226.

The method then advances to step 326, wherein, under the control of system controller 210, the Z-position of mask holder 228 is adjusted by use of motion control system 230 in order to ensure that shadow mask 226 does not touch substrate 114.

The method then advances to step 328, wherein, using the position correction information received from system controller 210 in step 322, the motion control system 230 adjusts the X-, Y-, and theta-position of mask holder 228 by an amount determined in step 322 in order to achieve proper alignment of shadow mask 226 to substrate 114.

The method then advances to step 330, wherein, under the control of system controller 210, the Z-position of mask holder 228 is adjusted by use of motion control system 230, such that shadow mask 226 is in close proximity to substrate 114.

The method then advances to step 332, wherein, under the control of system controller 210, magnetic chuck 216 is re-energized and, thus, a magnetic field is generated that pulls shadow mask 226 toward magnetic chuck 216. As a result, first surface 122 of substrate 114 is pulled into contact with contacting surface 218 of magnetic chuck 216, and contacting surface 234 of shadow mask 226 is pulled into contact with second surface 124 of substrate 114. Consequently, substrate 114 is now clamped or compressed between magnetic chuck 216 and shadow mask 226.

The method then advances to step 334, wherein a deposition process is performed, such as the deposition process described in connection with production system 100 of FIG. 1 or one of the deposition processes disclosed in U.S. Patent Application Publication No. 2003/0228715.

In summary, intimate contact between shadow mask 226 and substrate 114 within substrate holder system 112 is accomplished via switched magnetic chuck 216 which magnetically pulls shadow mask 226, which is formed of magnetic material, into intimate contact with substrate 114, which is sandwiched between magnetic chuck 216 and shadow mask 226. Consequently, substrate 114 is also pulled into intimate contact with magnetic chuck 216. Thermoelectric device 220 holds magnetic chuck 212 at a fixed, predetermined temperature. The intimate contact of magnetic chuck 216, substrate 114 and shadow mask 226 assures that heat is transferred uniformly and that all three are held at or near the same temperature during the shadow mask vacuum deposition process, thereby ensuring accurate registration between shadow mask 226 and substrate 114 is maintained. Additionally, the intimate contact between substrate 114 and shadow mask 226 avoids evaporant material from entering any gaps therebetween. Furthermore, system controller 210 controls magnetic chuck 216, thermoelectric device 220, CCD cameras 232, light sources 224, and motion control system 230 thereby rendering substrate holder system 112 amenable to an automated continuous vacuum deposition process.

The use of substrate holder system 112 and method 300 of the present invention is not limited to a production system configuration wherein the substrate translates serially from one vacuum deposition vessel to the next and wherein each vacuum deposition vessel contains a unique shadow mask. Those skilled in the art will recognize that the use of substrate holder system 112 and method 300 is easily adapted for a production system configuration wherein only one vacuum deposition vessel exists and multiple shadow masks and deposition sources are moved into and out of the vessel with each successive deposition event.

Additionally, the use of substrate holder system 112 and method 300 of the present invention is not limited to a production system configuration wherein the substrate translates via a reel-to-reel system. Those skilled in the art will recognize that substrate holder system 112 and method 300 may be adapted for use with a non-reel-to-reel system, i.e., a piece processing system, which would include a substrate holder frame. For example, in a non-reel-to-reel system the X-, Y-, Z- and theta-position adjustments may be made to either mask holder 228 or the substrate holder frame. In the case of the non-reel-to-reel system, it is desirable to distribute the positioning axis to both mask holder 228 and the substrate holder frame, i.e., X- and Y-position adjustments are applied to mask holder 228 and Z- and theta-position adjustments are applied to the substrate holder.

The present invention has been described with reference to the preferred embodiments. Obvious modifications and alterations will occur to others upon reading and understanding the preceding detailed description. For example, the positioning of light sources 224 on magnetic chuck 216 and the positioning of CCD cameras 232 on mask holder 228 are not to be construed as limiting the invention since it is envisioned that one or more light sources 224 can be positioned on mask holder 228 and one or more CCD cameras can be positioned on magnetic chuck 216. Moreover, the use of light sources 224 and CCD cameras 232 can be alternated on magnetic chuck 216 and mask holder 228. For example, one CCD camera and its corresponding light source can be positioned on mask holder 228 and magnetic chuck 216, respectively, while a second CCD camera and its corresponding light source can be positioned on magnetic chuck 216 and mask holder 228, respectively. It is intended that the invention be construed as including all such modifications and alterations insofar as they come within the scope of the appended claims or the equivalents thereof.

The invention claimed is:

1. A material deposition system comprising:
a magnetic chuck, said magnetic chuck switchable between a first state wherein magnetic flux generated by said magnetic chuck propagates from a contacting surface thereof and a second state wherein no magnetic flux propagates from the contacting surface thereof;
a magnetically conductive shadow mask, said shadow mask defining a contacting surface; and
means for movably supporting the contacting surface of said shadow mask in spaced parallel relation with the contacting surface of said magnetic chuck, wherein, in response to switching said magnetic chuck from the second state to the first state when a substrate is positioned between the contacting surface of said magnetic chuck and the contacting surface of said shadow mask, the magnetic flux generated by said magnetic chuck causes said shadow mask to be pulled toward said magnetic chuck whereupon said substrate is clamped between the contacting surface of said magnetic chuck and the contacting surface of said shadow mask.

2. The system of claim 1, wherein in response to switching said magnetic chuck from the first state to the second state, said supporting means moves said shadow mask away from said magnetic chuck thereby forming a gap between said substrate and the contacting surface of said shadow mask.

3. The system of claim 1, further including a material deposition source positioned on a side of said shadow mask opposite said magnetic chuck, said material deposition source operative for depositing a material on said substrate via said shadow mask when said substrate is clamped between the contacting surface of said magnetic chuck and the contacting surface of said shadow mask.

4. The system of claim 1, further including:
at least one thermal sensor operative for sensing a temperature of said magnetic chuck; and
a device operative for heating or cooling said magnetic chuck to a desired temperature as a function of the temperature sensed by said thermal sensor.

5. The system of claim 1, further including:
a light source coupled to one of said magnetic chuck and said supporting means, said light source operative for outputting a beam of light;
a camera coupled to the other of said magnetic chuck and said supporting means; and
a system controller operative for receiving an image output by said camera and for controlling at least one of said supporting means and a position of said substrate as a function of said image whereupon said camera is positioned to view the light beam output by said light source via an alignment aperture in said substrate.

6. The system of claim 1, wherein said supporting means includes:
a mask holder coupled to a side of said shadow mask opposite said magnetic chuck; and
a motion control system coupled to a side of said mask holder opposite said shadow mask.

7. The system of claim 6, further including:
a light source coupled to one of said magnetic chuck and said mask holder, said light source operative for outputting a beam of light;
a camera coupled to the other of said magnetic chuck and said mask holder; and
a system controller operative for receiving an image output by said camera and for controlling at least one of said motion control system and a position of said substrate as a function of said image whereupon said camera is positioned to view the light beam output by said light source via an alignment aperture in said substrate when said substrate is clamped between the contacting surface of said magnetic chuck and the contacting surface of said shadow mask.

8. The system of claim 1, further including:
a vacuum vessel having the magnetic chuck, the shadow mask and the supporting means positioned therein; and
means for translating at least a portion of the substrate into and out of the vacuum vessel.

9. A vapor deposition method comprising:
(a) positioning at least a portion of a substrate between a contacting surface of a magnetic chuck and a contacting surface of a shadow mask;
(b) switching said magnetic chuck from a first state wherein no magnetic flux propagates from the contacting surface thereof to a second state wherein magnetic flux propagates from the contacting surface thereof whereupon said shadow mask is pulled toward said magnetic chuck thereby clamping said substrate between the contacting surface of said magnetic chuck and the contacting surface of said shadow mask; and
(c) depositing a material on said substrate via at least one opening in said substrate.

10. The method of claim 9, further including:
(d) switching said magnetic chuck from the second state to the first state whereupon said shadow mask moves away from said magnetic chuck thereby forming a gap between said substrate and the contacting surface of said shadow mask.

11. The method of claim 10, further including:
(e) moving the portion of said substrate from between the contacting surface of said magnetic chuck and the contacting surface of said shadow mask.

12. The method of claim 9, further including:
heating or cooling said magnetic chuck; and
controlling said heating or cooling as a function of a temperature of said magnetic chuck.

13. The method of claim 9, further including between step (b) and step (c) the steps of:
in response to determining that said substrate and said shadow mask are misaligned, switching said magnetic chuck from the second state to the first state whereupon said shadow mask moves away from said magnetic chuck thereby forming a gap between said substrate and the contacting surface of said shadow mask;
repositioning at least one of said substrate and said shadow mask whereupon said substrate and said shadow mask are properly aligned; and
switching said magnetic chuck from the first state to the second state whereupon said substrate is clamped between the contacting surface of said magnetic chuck and the contacting surface of said shadow mask.

14. A material deposition system comprising:
a magnetic chuck operative between a first state where magnetic flux propagates from a contacting surface thereof and a second state wherein no magnetic flux propagates from the contacting surface thereof;
a magnetically conductive shadow mask having a contacting surface positioned in spaced relation with the contacting surface of said magnetic chuck;
means for supporting a substrate between the contacting surface of said magnetic chuck and the contacting surface of said shadow mask, wherein:
in response to said magnetic chuck entering the first state, said shadow mask and said magnetic chuck clamp said substrate between the contacting surfaces thereof; and
in response to said magnetic chuck entering the second state, said shadow mask and said magnetic chuck release said substrate.

15. The system of claim 14, further including a material deposition source operative for depositing a material on said substrate via one or more apertures in the shadow mask.

16. The system of claim 15, further including a vacuum vessel having said magnetic chuck, said shadow mask, said substrate and said material deposition source received therein, wherein said material deposition source deposits said material on said substrate in the presence of a vacuum in said vacuum vessel.

17. The system of claim 14, further including:
a temperature sensor for sensing a temperature of at least one of said magnetic chuck and said shadow mask and for outputting a temperature signal corresponding to the sensed temperature; and
a device for controlling the temperature of the at least one of said magnetic chuck and said shadow mask as a function of the temperature signal output by the temperature sensor.

18. The system of claim 14, further including:
a mask holder for supporting said shadow mask; and
a motion control system for supporting said mask holder and said shadow mask, said motion control system operative for at least one of:
rotating said mask holder and said shadow mask around an axis normal to the contacting surface of said shadow mask;
translating said mask holder and said shadow mask in a direction parallel to said axis; and
translating said mask holder and said shadow mask in at least one direction perpendicular to said axis.

19. The system of claim 18, further including:
a light source coupled to one of said magnetic chuck and said mask holder, said light source operative for outputting a beam of light;
a camera coupled to the other of said magnetic chuck and said mask holder, said camera operative for outputting an image of an object positioned in a field of view of said camera; and
a system controller operative for receiving the image output by said camera and for controlling at least one of said motion control system and a position of said substrate as a function of said image whereupon said camera is positioned to view the light beam output by said light source via a hole in said substrate.

20. A vacuum deposition method comprising:
(a) magnetically clamping a substrate between a chuck and a shadow mask;
(b) depositing a material on said substrate via at least one opening in said substrate; and
(c) releasing the magnetic clamp on said substrate whereupon at least one of said chuck and said shadow mask moves into spaced relation with said substrate.
